(19) United States
(12) Patent Application Publication
(10) Pub. No.: US 2025/0063822 A1
(43) Pub. Date: Feb. 20, 2025

(54) Contact Structures for Dual-Thickness Active Area SOI FETS

(71) Applicant: pSemi Corporation, San Diego, CA (US)

(72) Inventors: Jagar Singh, Clifton Park, NY (US); Kazuhiko Shibata, San Diego, CA (US); Simon Edward Willard, Irvine, CA (US)

(21) Appl. No.: 18/451,563

(22) Filed: Aug. 17, 2023

(51) Int. Cl. H01L 27/12; H01L 21/762; H01L 23/48; H01L 23/66; H01L 29/06; H01L 29/417

(52) U.S. Cl. CPC H01L 27/1207; H01L 21/76267; H01L 21/76283; H01L 23/481; H01L 23/66; H01L 29/0692; H01L 29/41775; H01L 2223/6616

(57) ABSTRACT

Structures and methods for better optimizing the performance of all the circuitry of an SOI IC. Embodiments include SOI IC having dual-thickness active areas, such that digital and non-RF analog circuitry may be fabricated on a relatively thin active layer while RF circuitry may be fabricated on a relatively thick active layer. Fabrication of RF circuitry on the relatively thick active layer allows for improvements to the R_{ON}*C_{OFF} figure of merit for the FET devices, and for optimizations not feasible for RF circuitry fabricated on a relatively thin active layer. Structures and methods for two-level shallow-trench isolation (STI) structures and electrical contacts are disclosed. Some embodiments may include a substrate contact extending from the substantially planar upper surface of a dielectric layer overlaying the thin and thick active areas to at least the BOX layer.

### BACKGROUND

### (1) Technical Field

The invention relates to electronic integrated circuits, and more particularly to radio frequency and digital circuitry fabricated with silicon-on-insulator technology.

### (2) Background

A challenge with electronic circuit design in general is that ideal components do not exist, particularly when dealing with radio frequency (RF) signals. For example, the operational characteristics of many passive and active components in an RF signal path are frequency dependent. As another example, a significant problem with RF circuit design is eliminating or controlling unwanted cross-effects (“cross-talk”) and self-effects, such as parasitic capacitances and inductances, undesired signal coupling, performance changes due to environment temperature changes as well as self-heating, and others. The problems of RF design become more acute when embodying RF circuits as integrated circuits (ICs), where components materials, circuit juxtaposition, and power constraints add to the difficulties of optimizing operational parameters for all components. As one example, field-effect transistors (FETs) are inherently designed to operate with fields, but fields do not have distinct edges and often cause cross-effects and self-effects. As another example, FETs have operating parameters that are subject to process, voltage, and temperature (PVT) variations. Accordingly, RF circuit designs embodied as ICs generally require optimizations of some circuit parameters at the expense of other parameters.

A notable characteristic of RF circuits in general is that different components may require different optimizations. For example, an antenna switch or amplifier in an RF signal path is generally an analog circuit optimized for performance at RF frequencies. Conversely, while the components of a bias voltage generation circuit for an antenna switch or amplifier are also generally analog circuitry, they generally do not operate at radio frequencies and they may need optimizations that differ from RF signal path components. Further, control circuitry for such circuits may include non-RF digital components that also may need optimizations that differ from RF signal path components. A distinct challenge of RF circuit design is that optimization for some circuitry may adversely affect optimization of other circuitry.

In general, RF signal path components are the most important circuitry to optimize. It was recognized some time ago that semiconductor-on-insulator (SOI) IC technology is particularly useful for such optimization. A conventional SOI IC includes a silicon (Si) substrate, a buried oxide layer (BOX) layer formed on the substrate, and an active layer of Si or silicon germanium (SiGe) formed on the BOX layer. In some applications, a trap-rich layer may be formed between the substrate and the BOX layer.

All of the circuitry—RF analog, non-RF analog, and digital—of a conventional SOI IC is generally fabricated in an active layer having a uniform thickness, such as about 550 Å. However, such a thin active layer is often not optimum for RF analog circuitry, many times limiting the application of appropriate back biasing and leading to a relatively high R_{ON}*C_{OFF} figure of merit.

The present invention addresses shortcomings of conventional SOI ICs, particularly for RF circuitry.

### SUMMARY

The present invention encompasses structures and methods for better optimizing the performance of all the circuitry—RF analog, non-RF analog, and digital—of an SOI IC. Embodiments include SOI IC having dual-thickness active areas, such that digital and non-RF analog circuitry may be fabricated on a relatively thin active layer (e.g., about 550 Å) while RF circuitry may be fabricated on a relatively thick active layer (e.g., about 2000 Å). Fabrication of RF circuitry on the relatively thick active layer allows for improvements to the R_{ON}*C_{OFF} figure of merit for the FET devices, and for optimizations not feasible (or in some cases, not possible) for RF circuitry fabricated on a relatively thin active layer. Embodiments of the present invention are particularly suitable for RF switches and amplifiers, including low-noise amplifiers (LNAs) and power amplifiers (PAS).

Depending on the relative thicknesses of the thin and thick layers, it may be challenging to concurrently form shallow-trench isolation (STI) structures in both active layers. One approach to overcoming this challenge is to fabricate “thin” and “thick” STIs in separate steps. Two methods of implementing this approach are described. A first method forms STIs in the thin active layer first, then in the thick active layer. A second method forms STIs in the thin active layer first and partial STIs in the thick active layer, then completes the partial STIs in the thick active layer in subsequent steps.

A similar approach is taken with forming electrical contacts to FETs within the thin and thick layers: a dielectric layer is formed having a first surface overlaying the thin active layer and the thick active layer and having a substantially planar second surface opposite the first surface; a first set of electrically conductive contacts is fabricated to extend from the substantially planar second surface of the dielectric layer to the at least one FET formed in and on the thin active layer; and a second set of electrically conductive contacts is fabricated to extend from the substantially planar second surface of the dielectric layer to the at least one FET formed in and on the thick active layer. Some embodiments may include a substrate contact extending from the substantially planar second surface of the dielectric layer to at least the BOX layer.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional diagram of a first example substructure of an SOI IC having dual-thickness active areas.

FIG. 1B is a stylized cross-sectional diagram of an example gate structure.

FIG. 2 is a stylized cross-sectional diagram of a second example substructure of an SOI IC having dual-thickness active areas.

FIG. 3A is a stylized cross-sectional diagram depicting a first stage in an additive method for fabricating dual-thickness active areas.

FIG. 3B is a stylized cross-sectional diagram depicting a second stage in an additive method for fabricating dual-thickness active areas.

FIG. 4A is a stylized cross-sectional diagram depicting a first stage in a subtractive method for fabricating dual-thickness active areas.

FIG. 4B is a stylized cross-sectional diagram depicting a second stage in a subtractive method for fabricating dual-thickness active areas.

FIG. 5 is stylized cross-sectional diagram depicting a multi-layer thick active layer AL_{THICK} suitable for use in embodiments of the present invention.

FIG. 6A is a stylized cross-sectional diagram of an example substructure of an SOI IC having a thick active layer AL_{THICK} FET in a fully depleted OFF state.

FIG. 6B is a stylized cross-sectional diagram of an example substructure of an SOI IC having a thick active layer AL_{THICK} FET in an ON state.

FIG. 6C is a stylized cross-sectional diagram of an example substructure of an SOI IC having a thick active layer AL_{THICK} FET in a partially depleted OFF state.

FIGS. 7A-7H are stylized cross-sectional diagrams of a first set of manufacturing stages for an example substructure of an SOI IC that is to have dual-thickness active areas.

FIGS. 8A-8H are stylized cross-sectional diagrams of a second set of manufacturing stages for an example substructure of an SOI IC that is to have dual-thickness active areas.

FIGS. 9A-9G are stylized cross-sectional diagrams of one set of manufacturing stages for forming FET regions and device contacts in an example of an SOI IC that has dual-thickness active areas.

FIG. 10 is a stylized cross-sectional diagram of a first example IC having dual-thickness active areas in which the thick active layer AL_{THICK} is adjacent to thin active layers AL_{THIN} on both sides.

FIG. 11 is a stylized cross-sectional diagram of a second example IC having dual-thickness active areas in which the thick active layer AL_{THICK} is adjacent to thin active layers AL_{THIN} on both sides.

FIG. 12 is a stylized cross-sectional diagram of a third example IC having dual-thickness active areas in which the thick active layer AL_{THICK} is adjacent to thin active layers AL_{THIN} on both sides.

FIG. 13 is a stylized cross-sectional diagram of one embodiment of a FET structure having a new configuration of an S-contact within a thick active layer AL_{THICK}.

FIG. 14 is a top plan view of a substrate that may be, for example, a printed circuit board or chip module substrate (e.g., a thin-film tile).

FIG. 15 is a process flow chart showing a first method for fabricating a substructure of an SOI IC having dual-thickness active areas.

FIG. 16 is a process flow chart showing a second method for fabricating a substructure of an SOI IC having dual-thickness active areas.

FIG. 17 is a process flow chart showing a first method for fabricating a substructure of an SOI IC having dual-thickness active areas.

FIG. 18 is a process flow chart showing a second method for fabricating a substructure of an SOI IC having dual-thickness active areas.

Like reference numbers and designations in the various drawings indicate like elements unless the context requires otherwise.

### DETAILED DESCRIPTION

The present invention encompasses structures and methods for better optimizing the performance of all the circuitry—RF analog, non-RF analog, and digital—of an SOI IC. Embodiments include SOI IC having dual-thickness active areas, such that digital and non-RF analog circuitry may be fabricated on a relatively thin active layer (e.g., about 550 Å) while RF circuitry may be fabricated on a relatively thick active layer (e.g., about 2000 Å). Fabrication of RF circuitry on the relatively thick active layer allows for improvements to the R_{ON}*C_{OFF} figure of merit for the FET devices, and for optimizations not feasible (or in some cases, not possible) for RF circuitry fabricated on a relatively thin active layer. Embodiments of the present invention are particularly suitable for RF switches and amplifiers, including low-noise amplifiers (LNAs) and power amplifiers (Pas).

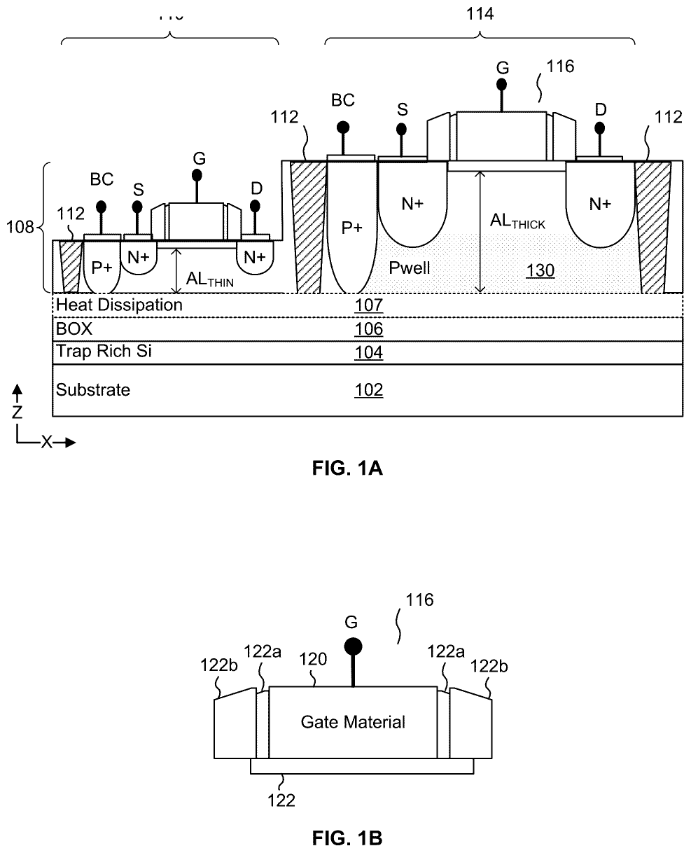

FIG. 1A is a stylized cross-sectional diagram of a first example substructure 100 of an SOI IC having dual-thickness active areas, fabricated using “front-end-of-line” processes. The illustrated substructure 100 includes a substrate 102, a trap-rich layer 104 formed on and/or in the substrate 102, and a BOX layer 106 formed on the trap-rich layer 104. The substrate 102 may be, for example, P-type Si, intrinsic Si, high-resistivity Si, porous Si, sapphire, or any other material compatible with SOI IC manufacture. In some embodiments, the trap-rich layer 104 may be omitted. In some embodiments, an optional heat dissipation layer 107 (e.g., silicon carbide, SiC) may be formed over the BOX layer 106 (or over the trap-rich layer 104 if the BOX layer 106 is not present).

Dual-thickness active areas 108 of a semiconductor (e.g., Si or SiGe) are formed on the BOX layer 106 and comprise a relatively thin active layer AL_{THIN} (e.g., at or below about 550 Å) formed adjacent to a relatively thick active layer AL_{THICK} (e.g., at or above about 1000 Å). Two methods of fabricating the dual-thickness active areas 108 are set forth below.

In the example illustrated in FIG. 1A, a first N-type FET 110 is formed in and on the thin active layer AL_{THIN} between surrounding isolation structures 112, such as shallow-trench isolation (STI) structures, and a second N-type FET 114 is formed in and on the thick active layer AL_{THICK} between surrounding isolation structures 112. Each N-type FET 110, 114 includes a body contact BC to a P+ doped region, a source contact S to an N+ region, a drain contact D to an N+ region, and a gate contact G to a gate structure 116. In the illustrated example, the N+ source and drain regions are shown as extending only partway to the BOX layer 106, but in some embodiments, the N+ source and drain regions may extend all of the way to the BOX layer 106. While NFETs are shown, P-type FETs may be formed as well by reversing all P and N materials, in known fashion.

FIG. 1B is a stylized cross-sectional diagram of an example gate structure 116. In the illustrated example, a gate material 120, such as polysilicon (p-Si), is formed on an insulator 122, such as silicon dioxide (SiO₂). One or more insulating spacers 122a, 122b (e.g., SiO₂ or silicon nitride (SiN)) are formed on the sides of the gate material 120. It should be appreciated that other gate structures, including replacement metal gates (RMGs), may be used in embodiments of the present invention. The fabrication of gate structures 116 is well-known in the art.

Not shown in FIG. 1A is a superstructure that would be formed on the active areas 108 in a “back-end-of-line” (BEOL) process. The superstructure generally comprises inter-layer dielectric (ILD) with formed layers of conductive material (e.g., metallization layers), and vertical conductors (vias) of various sizes. Portions of the metallization layers may be connected to bonding pads by corresponding vias. The completed IC may then be packaged using any of a number of known technologies (e.g., flip chips, ball-grid arrays, wafer level scale chip packages, wide-fan out packaging, and embedded packaging).

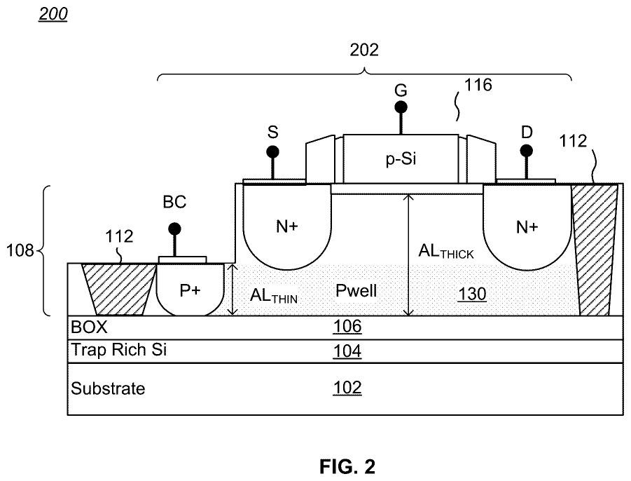

FIG. 2 is a stylized cross-sectional diagram of a second example substructure 200 of an SOI IC having dual-thickness active areas. Part of a single FET 202 is formed in and on a thick active layer AL_{THICK} while the remainder of the FET 202 is formed in the adjacent thin active layer AL_{THIN}. More specifically, in the illustrated example, a source contact S to an N+ region, a drain contact D to an N+ region, and a gate contact G to a gate structure 116 of the FET 202 are formed in and on the thick active layer AL_{THICK}. In the illustrated example, the N+ source and drain regions are shown as extending only partway to the BOX layer 106, but in some embodiments, the N+ source and drain regions may extend all of the way to the BOX layer 106.

Of note, a body contact BC to a P+ doped region is formed in the adjacent thin active layer AL_{THIN}. Accordingly, the layout of FETs on a substrate 102 supporting dual-thickness active areas 108 may cross the boundary between the thin active layer AL_{THIN} and the thick active layer AL_{THICK}.

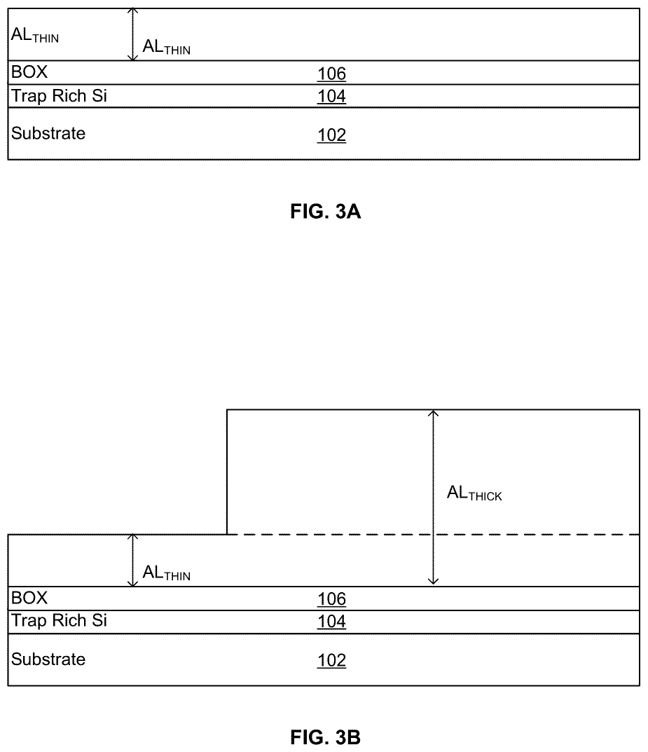

FIG. 3A is a stylized cross-sectional diagram depicting a first stage in an additive method for fabricating dual-thickness active areas. A starting point is a partial IC substructure comprising a substrate 102 (e.g., P-type Si), a trap-rich layer 104 formed on and/or in the substrate 102, and a BOX layer 106 formed on the trap-rich layer 104. In some embodiments, the trap-rich layer 104 may be omitted. A thin active layer AL_{THIN} is then formed on the BOX layer 106 by a suitable technology (e.g., epitaxial growth of Si) to a desired thickness (e.g., about 550 Å). Note that the depicted partial IC substructure and thin active layer AL_{THIN} are not to scale; for example, the substrate 102 alone may be about 775 μm thick.

FIG. 3B is a stylized cross-sectional diagram depicting a second stage in an additive method for fabricating dual-thickness active areas. After masking part of the thin active layer AL_{THIN} that is to remain unchanged, a thick active layer AL_{THICK} is formed by depositing semiconductor material on the unmasked thin active layer AL_{THIN}. Deposition may be by a suitable technology (e.g., epitaxial growth of Si) to a desired thickness (e.g., about 2000 Å including the thickness of the thin active layer AL_{THIN}). A thickness of about 1000 Å or more for the thick active layer AL_{THICK} increases electron mobility and application for RF switch circuits and LNA and PA devices and circuits. A thick active layer AL_{THICK} may also have enhanced channel strain compared to a thin active layer AL_{THIN}.

With any residual masking material removed, the partial IC substructure and dual-thickness active areas are ready for FET fabrication, such as is shown in FIGS. 1A and 2. Note that while only a single thin active layer AL_{THIN} and a single thick active layer AL_{THICK} are shown, a single IC die of a wafer may include more than one thin active layer AL_{THIN} and/or more than one thick active layer AL_{THICK}.

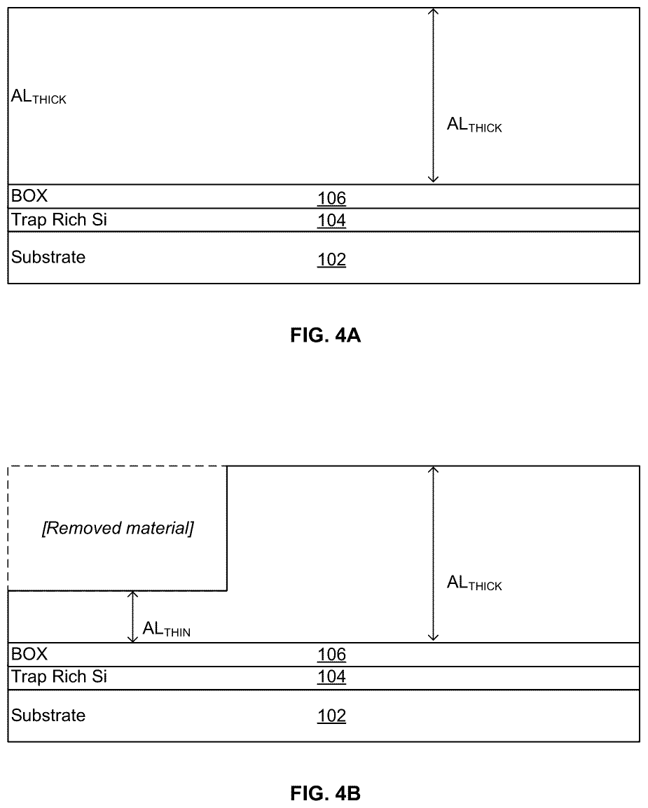

FIG. 4A is a stylized cross-sectional diagram depicting a first stage in a subtractive method for fabricating dual-thickness active areas. A starting point is a partial IC substructure comprising a substrate 102 (e.g., P-type Si), a trap-rich layer 104 formed on and/or in the substrate 102, and a BOX layer 106 formed on the trap-rich layer 104. In some embodiments, the trap-rich layer 104 may be omitted. A thick active layer AL_{THICK} is then formed on the BOX layer 106 by a suitable technology (e.g., epitaxial deposition of Si) to a desired thickness (e.g., about 2000 Å). Again, the depicted partial IC substructure and thick active layer AL_{THICK} are not to scale.

FIG. 4B is a stylized cross-sectional diagram depicting a second stage in a subtractive method for fabricating dual-thickness active areas. After masking part of the thick active layer AL_{THICK} that is to remain unchanged, a thin active layer AL_{THIN} is formed by thinning the unmasked thick active layer AL_{THICK} to a desired thickness (e.g., about 550 Å), such as by ion beam dry etching or chemical wet etching processes. With any residual masking material removed, the partial IC substructure and dual-thickness active areas are ready for FET fabrication, such as is shown in FIGS. 1A and 2. Note again that while only a single thin active layer AL_{THIN} and a single thick active layer AL_{THICK} are shown, a single IC die may include more than one thin active layer AL_{THIN} and/or more than one thick active layer AL_{THICK}.

Note that the doping levels of the thin active layer AL_{THIN} and the thick active layer AL_{THICK} may have different concentrations. Further, the top surface region of the thick active layer AL_{THICK} may be graded or retrograded to have little or no doping, so as behave very much like intrinsic Si or to essentially be intrinsic Si and thus exhibit higher carrier mobility. The added thickness of the thick active layer AL_{THICK} allows for greater opportunities to engineer the material in the P-well body region beneath the gate structure 116.

In general, circuitry that would not particularly benefit from being fabricated in and on the thick active layer AL_{THICK}—such as digital and non-RF analog circuitry—may be fabricated in and on the thin active layer AL_{THIN}. Accordingly, little or no change would be needed to existing fabrication steps to form active and/or passive devices in and on the thin active layer AL_{THIN}. Development time and cost should be reduced by using existing fabrication processes for circuitry that is suitable for the thin active layer AL_{THIN}.

RF analog circuitry, such as RF switches (e.g., antenna switches, signal switches), LNAs, and Pas, may be fabricated in the thick active layer AL_{THICK}. Advantages of the thick active layer AL_{THICK} with respect to fabrication of such circuitry are several. For example, the thick active layer AL_{THICK} may be formed in several layers of different materials that result in improved performance. A thin active layer AL_{THIN} generally is too thin to allow a multi-layer active layer. A multi-layer thick active layer AL_{THICK} may be fabricated using either the additive process or the subtractive process described above.

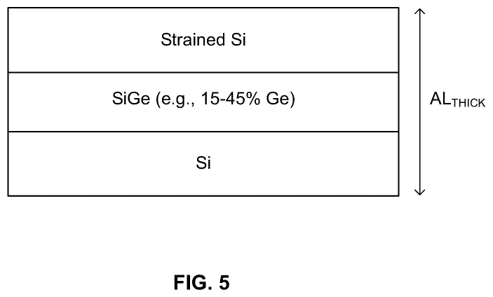

FIG. 5 is stylized cross-sectional diagram depicting a multi-layer thick active layer AL_{THICK} suitable for use in embodiments of the present invention. A first layer comprises Si, which may be doped (e.g., P+ or P−) or undoped (i.e., intrinsic Si). A second layer formed on the first layer is SiGe, an alloy of Si and about 15%-45% Ge. The second layer may be formed, for example, by diffusion of Ge into Si or by epitaxial growth. The SiGe layer provides a lattice constant larger than the lattice constant of the lower Si layer. A third layer of Si is formed on the second layer, such as by epitaxial growth. The lattice spacing of the Si third layer is forced to match the lattice constant of the SiGe layer, resulting in a tensile-strained Si layer that provides improved FET performance. For example, about 13% Ge in the SiGe second layer results in about a 25% increase in electron mobility and drain current in the channel of a FET formed in and on the Si third layer.

In some embodiments, the SiGe second layer may comprise sublayers, such as a graded SiGe sublayer formed by implantation of Ge into the Si first layer, a “relaxed” SiGe sublayer formed by chemical vapor deposition (CVD) or epitaxial growth on the graded SiGe sublayer and partially relaxed through the introduction of dislocations, and a “strained” SiGe sublayer formed by CVD or epitaxial growth on the relaxed SiGe sublayer.

Another advantage of fabricating FETs in the thick active layer AL_{THICK} is that there is sufficient vertical room to provide a body bias voltage per FET rather than using a single substrate bias voltage for all FETs. Not only does this allow independent biasing of each FET, but R_{ON} (and thus R_{ON}*C_{OFF}) can improve up to about 5% to about 10% with a body bias voltage of 0V or just slightly positive voltage, compared to a conventional substrate bias voltage of about −3.0 or −3.5V for switch operation. For example, FIGS. 1A and 2 both show FETs with top-access body contacts BC coupled to corresponding body contact P+ doped regions that extend through the thick active layer AL_{THICK} to the BOX layer 106, and shallower N+ source S and drain D regions. With a thick active layer AL_{THICK}, an elongated body contact P+ region, and shallow S and D regions, the resistance R_{B} of the body region underneath the gate structure 116 to the body contact P+ doped region is less than in a thin active layer AL_{THIN}, resulting in faster and more complete depletion of the FET channel when transitioning to the OFF state.

Moreover, when using the additive process described above, since all of the thin active layer AL_{THIN} is exposed before formation of an overlying thick active layer AL_{THICK}, some or all of the thin active layer AL_{THIN} that will underlie the thick active layer AL_{THICK} may be doped (e.g., with a P-type material such as Indium for an NFET) to further lower the resistance R_{B} of the P-well body region—see region 130 in FIGS. 1A and 2. Since the doped thin active layer AL_{THIN} will be spaced from the top surface of the added semiconductor material comprising the rest of the thick active layer AL_{THICK}, such doping in the underlying thin active layer AL_{THIN} should have little effect on carrier mobility in the channel of a FET fabricated in and on the overlying portion of the thick active layer AL_{THICK}. Of note, the lower resistance R_{B} of the P-well body region in the thick active layer AL_{THICK} should help to improve the breakdown voltage BV_{DSS}, reliability, and linearity of FETs formed in the thick active layer AL_{THICK}, particularly for SOI N-type Extended Drain MOS (EDMOS) FETs.

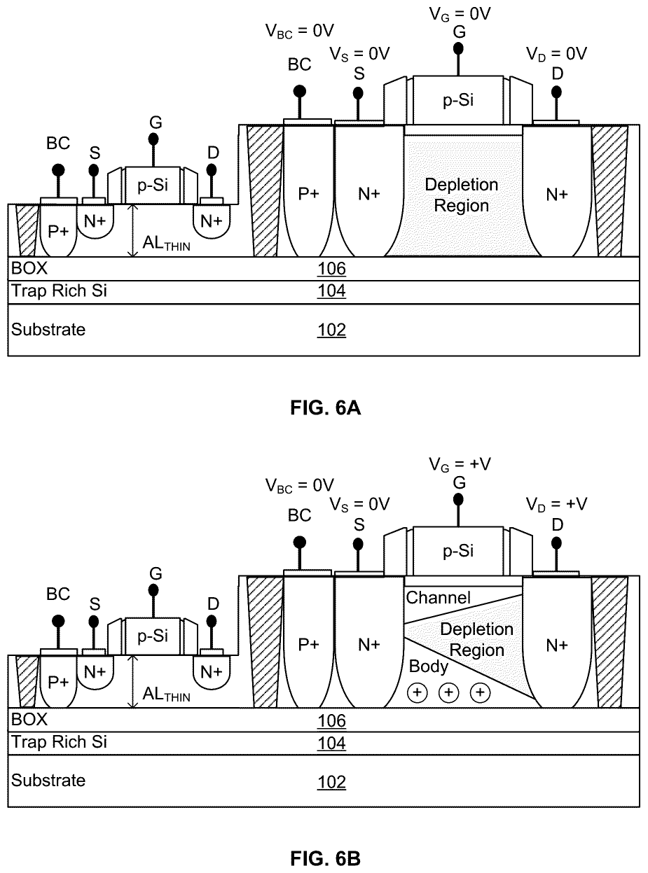

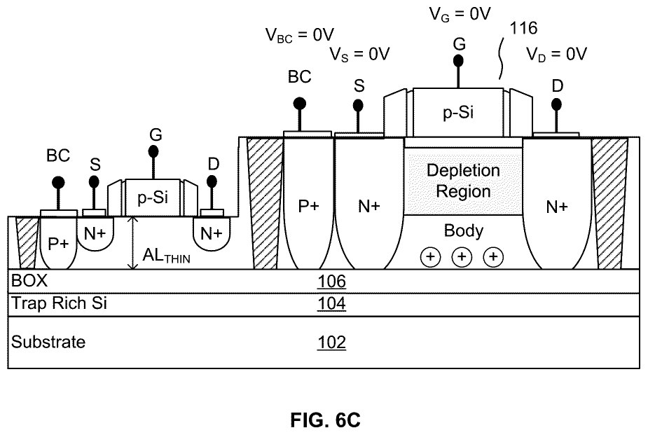

FIG. 6A is a stylized cross-sectional diagram of an example substructure of an SOI IC having a thick active layer AL_{THICK} FET in a fully-depleted OFF state. For the voltages shown in FIG. 6A, the P-well of the FET in the thick active layer AL_{THICK} will be fully depleted if the top of the P-well is essentially intrinsic Si, such as by retrograding the Si deposited to complete the thick active layer AL_{THICK}. The gate voltage V_{G} is shown in FIG. 6A as 0V, but can be a negative voltage (e.g., −3.5V or −5V) to turn the FET OFF faster and prevent current leakage between the source S and drain D. The body contact voltage V_{BC} may also be a negative voltage. Full depletion reduces harmonics in applied RF signals. Note that the thickness selection for the thick active layer AL_{THICK} in RF switch applications is tied to having full depletion in an OFF-state operation—high thickness values for the thick active layer AL_{THICK} may result in only partial depletion.

FIG. 6B is a stylized cross-sectional diagram of an example substructure of an SOI IC having a thick active layer AL_{THICK} FET in an ON state. For the voltages shown in FIG. 6B, a conduction channel is formed in the P-well of the FET while a portion of the P-well is partially depleted. Turn-on of the FET is dominated by the essentially intrinsic Si at the top of the P-well and is generally quite fast.

FIG. 6C is a stylized cross-sectional diagram of an example substructure of an SOI IC having a thick active layer AL_{THICK} FET in a partially depleted OFF state. In some applications, particularly for RF switches, speed of switching states between ON and OFF is often a critical design goal. A FET having a thick active layer AL_{THICK} enables a partially-depleted OFF state that depletes the channel underneath the gate structure 116 but leaves some body charge (indicated in FIG. 6C by “+” symbols) between the depletion region and the BOX layer 106. The result is that the thick active layer AL_{THICK} FET can be more rapidly turned ON and OFF, since the depletion region is limited to the upper regions of the body beneath the gate structure 116.

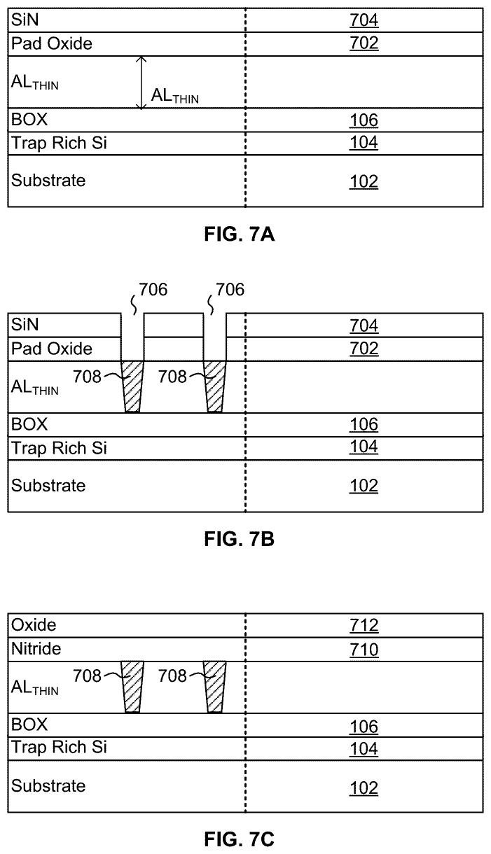

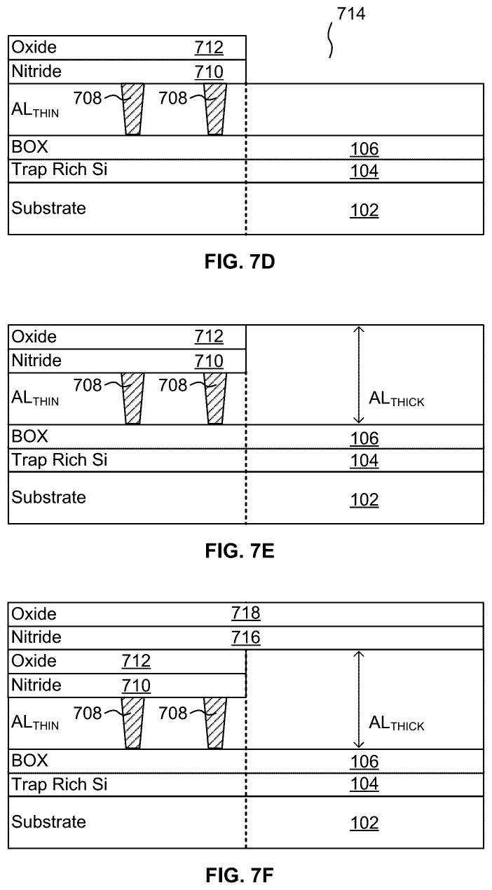

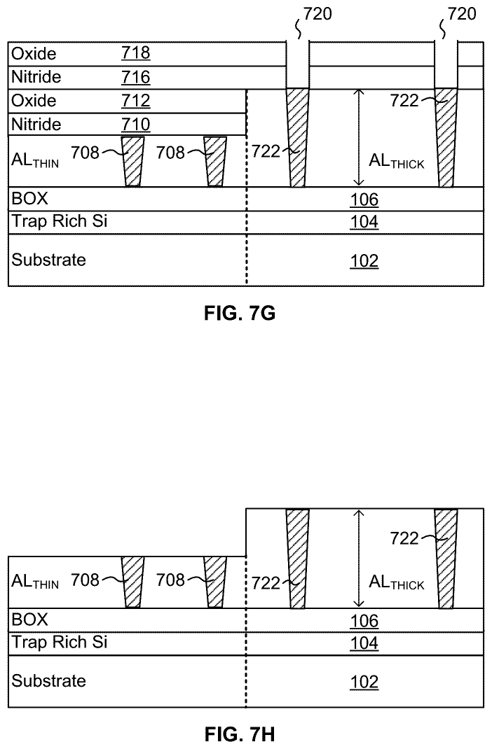

Depending on the relative thicknesses of the AL_{THIN} and AL_{THICK} layers, it may be challenging to concurrently form STIs in both the thin active layer AL_{THIN} and the thick active layer AL_{THICK}, for example, because of focus issues for photolithographic process steps. One approach to overcoming this challenge is to fabricate “thin” and “thick” STIs in separate steps. For example, FIGS. 7A-7H are stylized cross-sectional diagrams of a first set of manufacturing stages for an example substructure of an SOI IC that is to have dual-thickness active areas.

In FIG. 7A, a starting point is a partial IC substructure comprising a substrate 102 (e.g., P-type Si), a trap-rich layer 104 formed on and/or in the substrate 102, and a BOX layer 106 formed on the trap-rich layer 104. In some embodiments, the trap-rich layer 104 may be omitted. A thin active layer AL_{THIN} is then formed on the BOX layer 106 by a suitable technology (e.g., epitaxial growth of Si) to a desired thickness (e.g., about 550 Å). A pad oxide 702 is formed on the thin active layer AL_{THIN}, and a first SiN layer 704 is formed on the pad oxide 702. The combination of materials may comprise a first masking layer, but other conventional masking processes may be used for the first masking layer.

In FIG. 7B, the pad oxide 702 and the first SiN layer 704 are lithographically patterned and etched to create openings 706 for the fabrication of STIs within the portion of the IC substructure that is to retain a thin active layer AL_{THIN}. STIs 708 are then formed by etching an opening or void through the exposed thin active layer AL_{THIN} and filling the etched opening or void with a suitable material (e.g., SiO₂, CVD oxide, or high-density plasma oxide). The pad oxide 702 and the first SiN layer 704 may be removed, such as by chemical-mechanical polishing (CMP).

In FIG. 7C, a second SiN layer 710 and a first oxide layer 712 are laid down over the thin active layer AL_{THIN}. The combination of materials may comprise a second masking layer, but other conventional masking processes may be used for the second masking layer.

In FIG. 7D, the second SiN layer 710 and the first oxide layer 712 are lithographically patterned and etched to create an opening 714 for the fabrication of the thick active layer AL_{THICK}.

In FIG. 7E, the remaining material for the thick active layer AL_{THICK} is deposited within the (former) opening 714, such as by epitaxial growth of Si.

In FIG. 7F, a third SiN layer 716 and a second oxide layer 718 are laid down over the thick active layer AL_{THICK} and the second SiN layer 710 and the first oxide layer 712 The combination of materials may comprise a third masking layer, but other conventional masking processes may be used for the third masking layer. In some embodiments, only the thick active layer AL_{THICK} is covered by the third masking layer.

In FIG. 7G, the third SiN layer 716 and the second oxide layer 718 are lithographically patterned and etched to create openings 720 for the fabrication of STIs within the portion of the IC substructure that is to have a thick active layer AL_{THICK}. STIs 722 are then formed by etching a void through the exposed thick active layer AL_{THICK} and filling the etched void with a suitable material. Note that the STI material and fabrication process for the STIs 722 of this stage need not be the same material used for the “thin” STI's 708.

In FIG. 7H, the remaining oxides and nitride layers have been removed, such as by CMP, leaving a substructure of an SOI IC having dual-thickness active areas with corresponding STIs 708, 722.

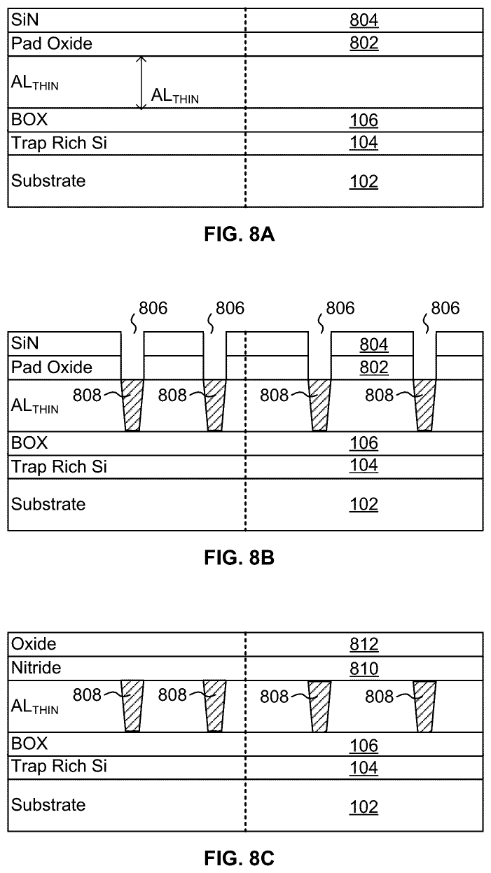

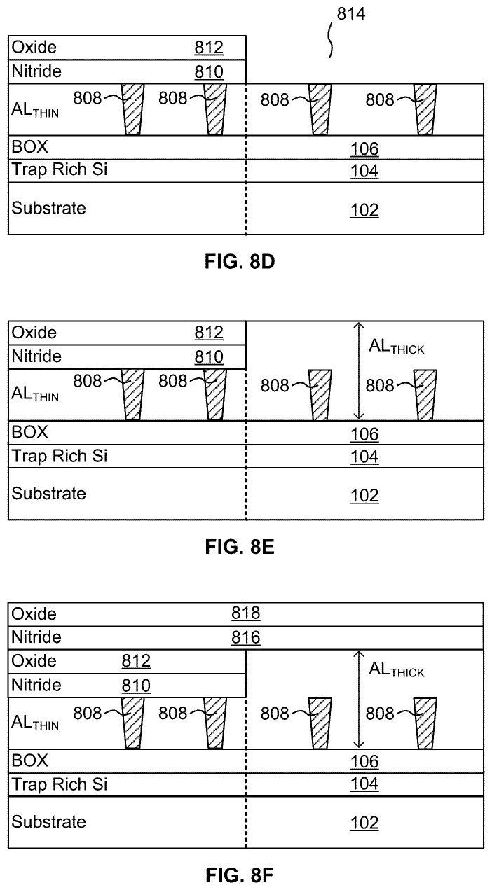

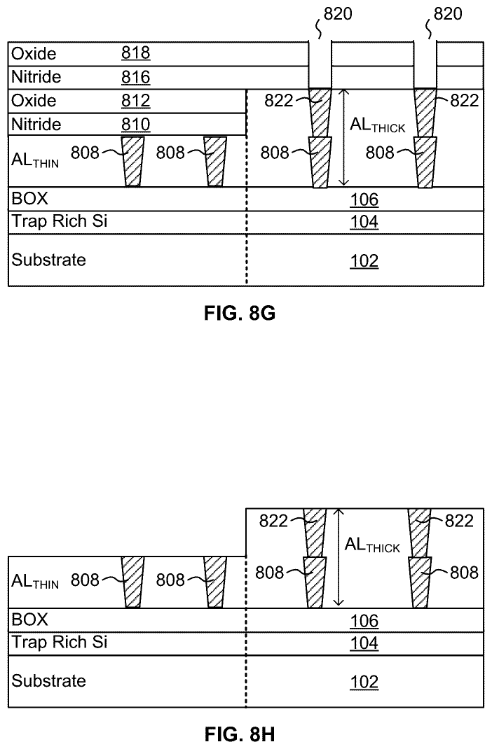

As another example, FIGS. 8A-8H are stylized cross-sectional diagrams of a second set of manufacturing stages for an example substructure of an SOI IC that is to have dual-thickness active areas.

In FIG. 8A, a starting point is a partial IC substructure comprising a substrate 102 (e.g., P-type Si), a trap-rich layer 104 formed on and/or in the substrate 102, and a BOX layer 106 formed on the trap-rich layer 104. In some embodiments, the trap-rich layer 104 may be omitted. A thin active layer AL_{THIN} is then formed on the BOX layer 106 by a suitable technology (e.g., epitaxial growth of Si) to a desired thickness (e.g., about 550 Å). A pad oxide 802 is formed on the thin active layer AL_{THIN}, and a first SiN layer 804 is formed on the pad oxide 802.

In FIG. 8B, the pad oxide 802 and the first SiN layer 804 are lithographically patterned and etched to create openings 806 for the fabrication of STIs. STIs 808 are then formed by etching a void through the exposed thin active layer AL_{THIN} and filling the etched void with a suitable material. The pad oxide 802 and the first SiN layer 804 may be removed, such as by CMP.

In FIG. 8C, a second SiN layer 810 and a first oxide layer 812 are laid down over the thin active layer AL_{THIN}.

In FIG. 8D, the second SiN layer 810 and the first oxide layer 812 are lithographically patterned and etched to create an opening 814 for the fabrication of the thick active layer AL_{THICK}.

In FIG. 8E, the remaining material for the thick active layer AL_{THICK} is deposited within the (former) opening 814, such as by epitaxial growth of Si.

In FIG. 8F, a third SiN layer 816 and a second oxide layer 818 are laid down over the thick active layer AL_{THICK} and the second SiN layer 810 and the first oxide layer 812.

In FIG. 8G, the third SiN layer 816 and the second oxide layer 818 are lithographically patterned and etched to create openings 820 for the fabrication of STIs within the portion of the IC substructure that is to have a thick active layer AL_{THICK}. A second set of STIs 822 are then formed by etching a void through the exposed thick active layer AL_{THICK} to at least the tops of the first set of STIs 808 formed within lower portion of the thick active layer AL THICK and filling the etched void with a suitable material. Note that the STI material and fabrication process for the STIs 822 of this stage need not be the same material used for the “thin” STI's 808. For example, the thin or lower STI's 808 may be made using SiO₂ while the upper STI's 822 may be made using high-density plasma oxide.

In FIG. 8H, the remaining oxides and nitride layers have been removed, such as by CMP, leaving a substructure of an SOI IC having dual-thickness active areas with corresponding STIs 808, 822.

It may be noted that the bottoms of the second set of STIs 822 need not exactly match the tops of the corresponding first set of STIs 808 within the thick active layer AL_{THICK}, but may be smaller or larger. The second set of STIs 822 may even penetrate somewhat into the first set of STIs 808 within the thick active layer AL_{THICK} if the etchant used to make openings 820 is somewhat aggressive or used too long.

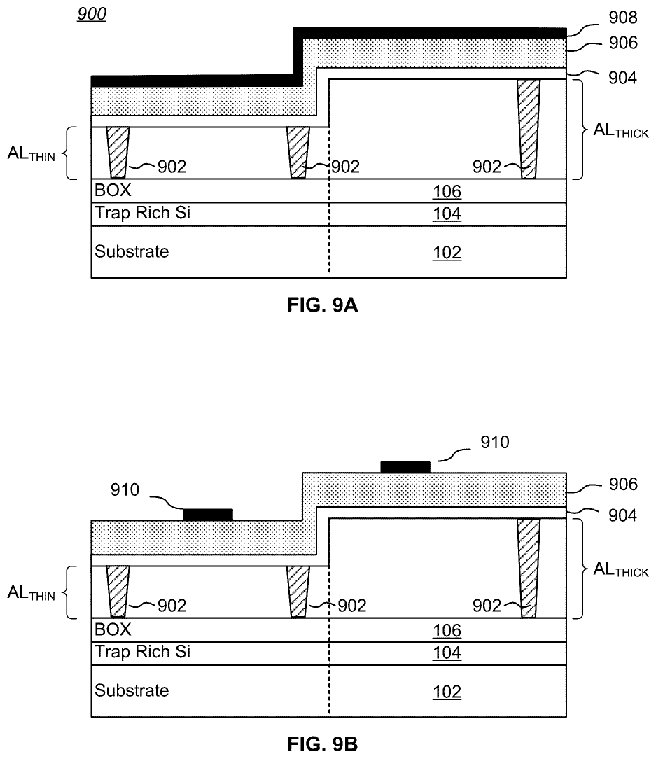

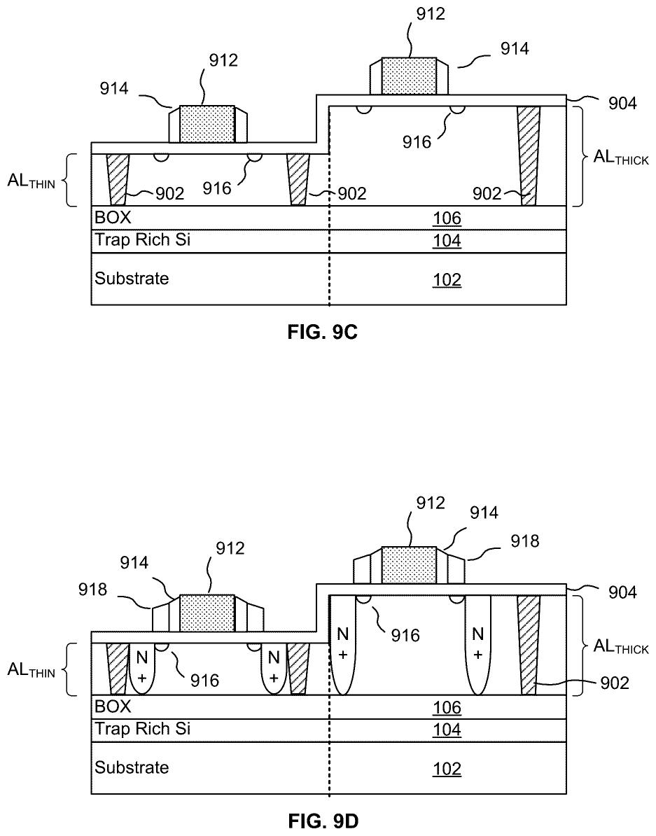

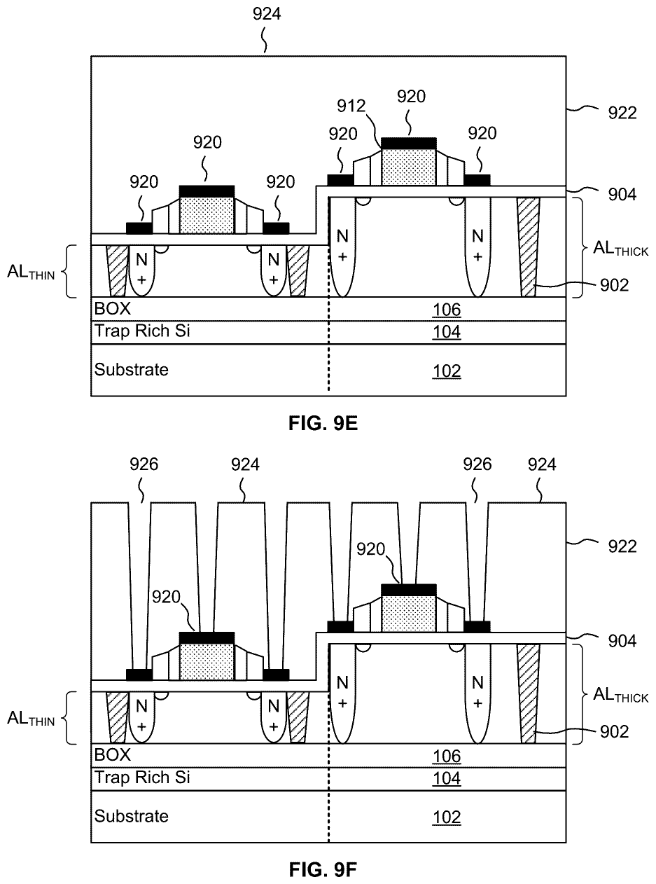

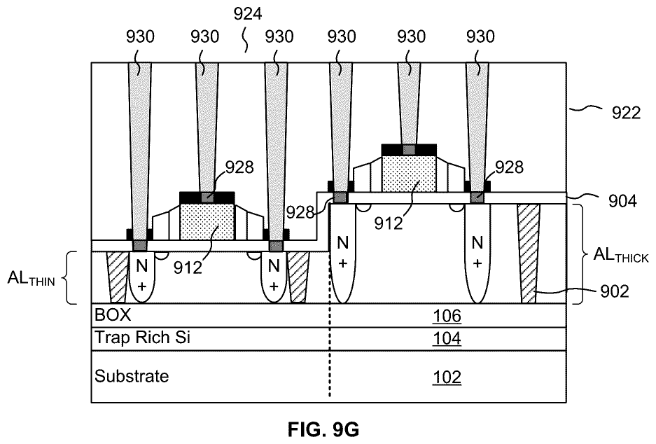

Another challenge that may be posed when fabricating a dual-thickness active area IC is formation of FET regions (e.g., source S, drain D, and gate G) within the IC substructure, and formation of device contacts (e.g., to the source S, drain D, gate G of a FET) within the superstructure of the IC, for example, because of focus issues for conventional photolithographic process steps. One approach to overcoming this challenge is to separately process the “thin” and “thick” thin active layer AL_{THIN} and the thick active layer AL_{THICK}. For example, FIGS. 9A-9G are stylized cross-sectional diagrams of one set of manufacturing stages for forming FET regions and device contacts in an example of an SOI IC that has dual-thickness active areas.

In FIG. 9A, the example fabrication stage starts with an IC substructure 900 having dual-thickness active areas and formed STIs 902, such as the example shown in FIG. 7H (although the example shown in FIG. 8H may also be used). A thin oxide layer 904 is applied over the substructure 900, such as by a thermal oxidation process, CVD, or atomic layer deposition (ALD). The thin oxide layer 904 will serve as the gate oxide of the FETs being formed. A polysilicon layer 906 is formed over the oxide layer 904, such as by thermal oxidation and CVD. Next, a hardmask 908 is applied over the polysilicon layer 906, such as by CVD. The material of the hardmask 908 may be, for example, amorphous silicon carbide.

In FIG. 9B, the hardmask 908 is photoresist patterned and etched using conventional MOSFET techniques to define gate locations 910. Due to the disparity in height between the thin active layer AL_{THIN} and the thick active layer AL_{THICK}, the hardmask 908 may need to be patterned and etched twice: once for the thin active layer AL_{THIN} and once for the thick active layer AL_{THICK} (the order should not matter).

In FIG. 9C, the polysilicon layer 906 has been etched around each hardmask 908 down to the oxide layer 904 and the hardmask 908 removed (by wet or dry chemical etching), leaving a core of polysilicon material defining a gate structure 912 on the thin active layer AL_{THIN} and the thick active layer AL_{THICK}. In addition, a first set of spacers 914 (e.g., SiO₂ or Si) are formed on the sides of the gate structure 912, which may need to be done in separate steps (thin-side/thick-side) with respect to removing excess material. At this point, some optional regions 916 may be fabricated near the side edges of the gate structure 912, such as halo implants and/or lightly-doped drain (LDD) implants, for example, to control short-channel effects. Implantation generally may be performed on both the thin active layer AL_{THIN} and the thick active layer AL_{THICK} simultaneously.

In FIG. 9D, a second set of spacers 918 (e.g., SiO₂ or Si) are formed on the sides of the gate structure 912 (thus extending the first set of spacers 914). Formation of the second set of spacers 918 may need to be done in separate steps (thin-side/thick-side) with respect to removing excess material. At this point, the source and drain regions (indicated by N+, since this example is for NFETs) may be implanted on either side of the gate structure 912. In some embodiments, the source/drain implantation generally may be performed on both the thin active layer AL_{THIN} and the thick active layer AL_{THICK} simultaneously. In some embodiments, the source/drain implantation generally may be performed separately on the thin active layer AL_{THIN} and the thick active layer AL_{THICK}, allowing different dopant concentrations for the two active layers, and/or deeper implantation in the thick active layer AL_{THICK}.

At this point, the substructure 900 is substantially complete and formation of the superstructure may commence. It should be appreciated that a number of other embodiments of the disclosed substructure having dual-thickness active areas may include additional or variant structures, features, and materials compatible with CMOS IC fabrication processes. Thus, a number of other structure, region, and/or layer formations may be created during the fabrication of the substructure 900 without departing from the spirit of the invention, and some steps may be performed in a different order. As should also be clear, while NFETs are shown by way of example, P-type FETs may be formed as well by reversing all P and N materials, in known fashion. Thus, the FETs in FIGS. 9A-9D may be both NFETs, both PFETs, or an NFET on the thin active layer AL_{THIN} with a PFET on the thick active layer AL_{THICK}, or a PFET on the thin active layer AL_{THIN} with a PFET on the thick active layer AL_{THICK}.

As noted above, an IC superstructure generally comprises inter-layer dielectric (ILD) with formed layers of conductive material (e.g., metallization layers), and vertical conductors (vias) of various sizes. Thus, an IC superstructure is typically fabricated layer by layer. For an IC having dual-thickness active areas, it is generally useful to essentially “planarize” the top of the IC for purposes of further IC processing, which avoids having to change most BEOL steps. A novel aspect of the present invention is a set of transition steps that adapt an IC having dual-thickness active areas to a form having an essentially “planar” top by forming electrically conductive via contacts from a planar top surface to the source, drain, and gate of each FET regardless of location on a thin active layer AL_{THIN} or a thick active layer AL_{THICK}.

In FIG. 9E, the IC is photoresist patterned and etched to outline the N+ source, drain regions, and the gate structure 912. A contact etch stop layer (CESL) 920, such as a thin (e.g., 100 Å) layer of SiN, is then deposited over the N+ source and drain regions and over the gate structure 912. Alternatively, a CESL layer 920 may be deposited over the entire IC, and then patterned and etched to remove the layer material except over the N+ source and drain regions and over the gate structure 912. The purpose of the CESL layer 920 is to affirmatively stop a subsequent etchant from damaging the underlying structures. A dielectric layer 922, such as SiO₂, may then be overlayed on the IC to effectively even-out the height disparity between the thin active layer AL_{THIN} and the thick active layer AL_{THICK}, essentially creating a planar top 924. It may also be useful to further planarize the planar top 924 by CMP or the like for purposes of further IC processing.

In FIG. 9F, the planar top 924 of the dielectric layer 922 is then photoresist patterned and etched to define areas over the CESL layer 920. An etching process (e.g., dry oxide etching) is then applied to etch voids 926 through the dielectric layer 922 down to the CESL layer 920. If the etchant is highly anisotropic or if the disparity in height between the thin active layer AL_{THIN} and the thick active layer AL_{THICK} is sufficiently small, etching may proceed concurrently on both the thin and thick sides of the IC. Otherwise, the planar top 924 of the dielectric layer 922 is patterned and etched twice, once for the thin active layer AL_{THIN} and once for the thick active layer AL_{THICK} (the order should not matter), to make the voids 926.

In FIG. 9G, the CESL layer 920 at the bottom of the voids 926 is removed, such as by wet etching. In addition, the thin oxide layer 904 overlying the N+ source and drain regions may be removed in order to allow optional deposition of a silicide metal 928 on the exposed N+ source and drain regions, as well as on the gate structure 912. The voids 926 may then be filled by deposition of a low-resistivity contact material 930, such as TiSi, NiSi, TaN, W, etc., forming electrically conductive via contacts from the top planar top 924 of the dielectric layer 922 to the N+ source and drain regions and the gate structure 912.

At this point, the IC may be further processed by conventional BEOL steps, such as by adding metallization layers and additional vias. Portions of the metallization layers may be connected to bonding pads by corresponding vias. The completed IC may then be packaged using any of a number of known technologies (e.g., flip chips, ball-grid arrays, wafer level scale chip packages, wide-fan out packaging, and embedded packaging).

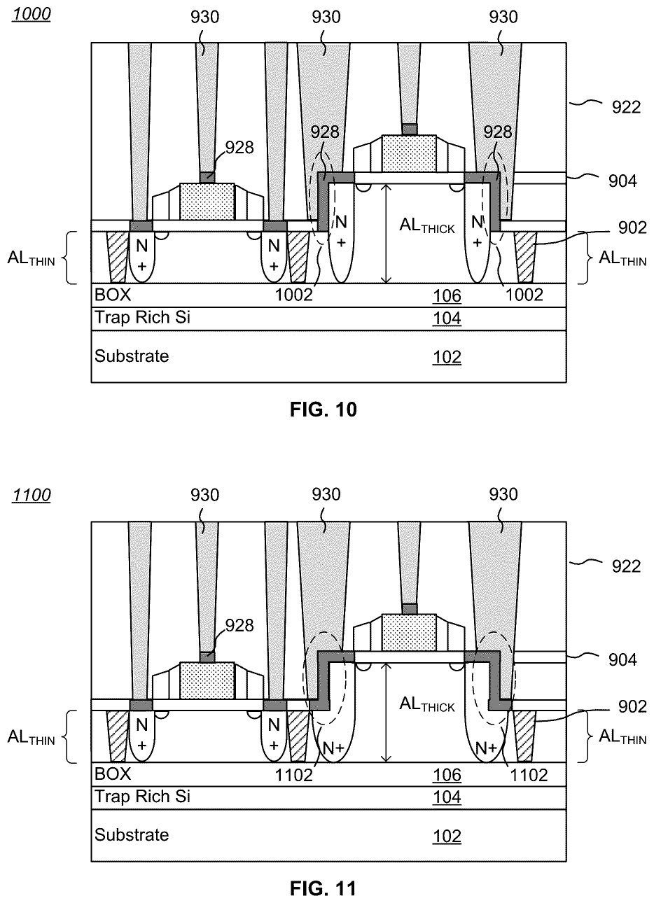

The ability to have a thick active layer AL_{THICK} adjacent a thin active layer AL_{THIN} provides additional design flexibility that may enable increased performance of an IC. For example, FIG. 10 is a stylized cross-sectional diagram of a first example IC 1000 having dual-thickness active areas in which the thick active layer AL_{THICK} is adjacent to thin active layers AL_{THIN} on both sides. In the illustrated example, the sides (within ovals 1002) of the N+ regions of a FET in the thick active layer AL_{THICK} extend above the thin active layer AL_{THIN} and are coated with a silicide metal in a “sidewall” configuration. Accordingly, the contact material 930 can contact a greater surface area of the corresponding for the N+ source and drain regions, thus reducing the contact resistance R_{C} as well as the source resistance R_{S} and drain resistance R_{D}. Reduction of those resistances using a sidewall configuration improves the device performance by allowing greater current flow for the same amount of resistive heating or the same amount of current flow with less resistive heating compared to a non-stepped configuration. In some embodiments, the contact material 930 may only connect to one sidewall of a FET in the thick active layer AL_{THICK}.

FIG. 11 is a stylized cross-sectional diagram of a second example IC 1100 having dual-thickness active areas in which the thick active layer AL_{THICK} is adjacent to thin active layers AL_{THIN} on both sides. A variant of the sidewall configuration of FIG. 10, the example of FIG. 11 shows “stepped” N+ source and drain regions (within ovals 1102) that extend into the adjacent thin active layers AL_{THIN}. Accordingly, the contact material 930 can contact an even greater surface area of the corresponding for the N+ source and drain regions, thus reducing the contact resistance R_{C} as well as the source resistance R_{S} and drain resistance R_{D}.

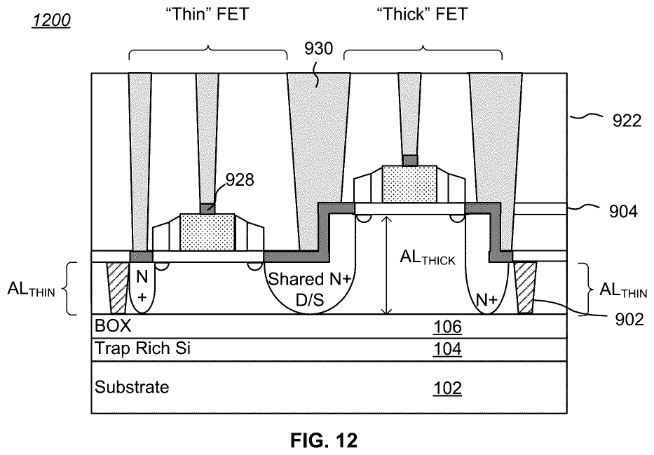

FIG. 12 is a stylized cross-sectional diagram of a third example IC 1100 having dual-thickness active areas in which the thick active layer AL_{THICK} is adjacent to thin active layers AL_{THIN} on both sides. A variant of the stepped configuration of FIG. 11, in the illustrated example, the STI 902 that separated the “thin” FET from the “thick” FET of FIG. 10 is omitted so that the drain of the “thin” FET is shared with the source of the “thick” FET, reducing the area needed for two FETs coupled in series.

In some embodiments of SOI IC having dual-thickness active areas, it may be useful to include “substrate contacts” or “S-contacts”. S-contacts are generally low-resistivity conductive structures that are formed from the superstructure of a MOSFET IC through the active layer and BOX layers to (or close to) the IC substrate. Uses of S-contacts have included mitigation of accumulated charge effects that adversely affect the FET, for shielding, and/or for thermal conduction. Examples of applications of some forms of S-contacts are set forth in U.S. Pat. No. 9,837,412, issued Dec. 5, 2017, entitled “S-Contact for SOI”, in U.S. Pat. No. 9,960,098, issued May 1, 2018, entitled “Systems and Methods for Thermal Conduction Using S-Contacts”, and in U.S. Pat. No. 10,276,371, issued Apr. 30, 2019, entitled “Managed Substrate Effects for Stabilized SOI FETS”, all of which are hereby incorporated by reference.

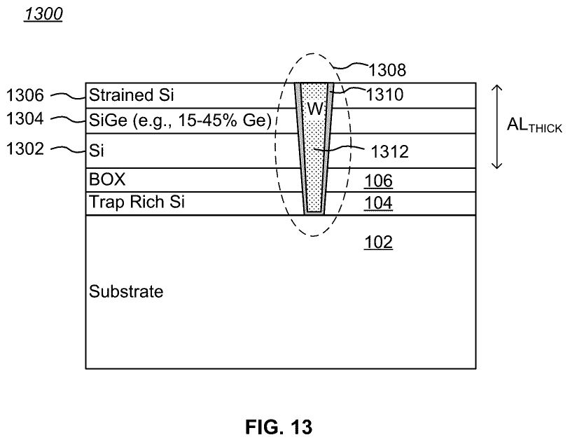

FIG. 13 is a stylized cross-sectional diagram of one embodiment of a FET structure 1300 having a new configuration of an S-contact within a thick active layer AL_{THICK}. The illustrated substructure 100 includes a substrate 102, a trap-rich layer 104 formed on and/or in the substrate 102, and a BOX layer 106 formed on the trap-rich layer 104. Formed on the BOX layer 106 is a multi-layer thick active layer AL_{THICK} such as is described above with respect to FIG. 5. A first layer 1302 comprises Si, which may be doped (e.g., P+ or P−) or undoped (i.e., intrinsic Si). A second layer 1304 formed on the first layer is SiGe, an alloy of Si and about 15%-45% Ge. The second layer 1304 may be formed, for example, by diffusion of Ge into Si or by epitaxial growth. The SiGe layer provides a lattice constant larger than the lattice constant of the lower Si layer. A third layer 1306 of strained Si is formed on the second layer 1304, such as by epitaxial growth.

In the illustrated example, a void (encompassed by oval 1308, now filled) defining the location of an S-contact is formed by patterning and etching the FET structure 1300 down to a desired level; the void extends to the substrate 102 in the illustrated example, by may be stopped at a higher level, such as the BOX level 106 or even on of the layers of the multi-layer thick active layer AL_{THICK}. After the void is created, it may be lined with an outer shell 1310 of a conductive barrier material, such as TiN, to prevent diffusion between the surrounding doped silicon or silicon alloys and an inner core of the S-contact. The inner portion of the void is then filled with a core 1312 of low-resistivity conductive material, such as tungsten (W). A number of similar S-contacts may be formed as a ring around a single FET or a group of FETs as desired.

Circuits and devices in accordance with the present invention may be used alone or in combination with other components, circuits, and devices. Embodiments of the present invention may be fabricated as integrated circuits (ICs), which may be encased in IC packages and/or in modules for case of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

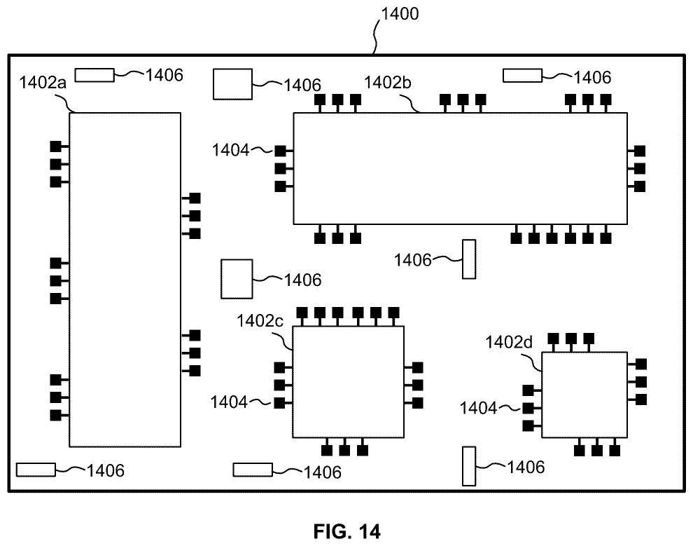

As one example of further integration of embodiments of the present invention with other components, FIG. 14 is a top plan view of a substrate 1400 that may be, for example, a printed circuit board or chip module substrate (e.g., a thin-film tile). In the illustrated example, the substrate 1400 includes multiple ICs 1402a-1402d having terminal pads 1404 which would be interconnected by conductive vias and/or traces on and/or within the substrate 1400 or on the opposite (back) surface of the substrate 1400 (to avoid clutter, the surface conductive traces are not shown and not all terminal pads are labelled). The ICs 1402a-1402d may embody, for example, signal switches, active and/or passive filters, amplifiers (including one or more LNAs), and other circuitry. For example, IC 1402b may incorporate one or more instances of an SOI IC having dual-thickness active areas.

The substrate 1400 may also include one or more passive devices 1406 embedded in, formed on, and/or affixed to the substrate 1400. While shown as generic rectangles, the passive devices 1406 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1400 to other passive devices 1406 and/or the individual ICs 1402a-1402d. The front or back surface of the substrate 1400 may be used as a location for the formation of other structures.

Embodiments of the present invention are useful in a wide variety of larger radio frequency (RF) circuits and systems for performing a range of functions, including (but not limited to) RF switches, RF power amplifiers, RF low-noise amplifiers (LNAs), RF phase shifters, RF attenuators, antenna beam-steering systems, charge pump devices, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

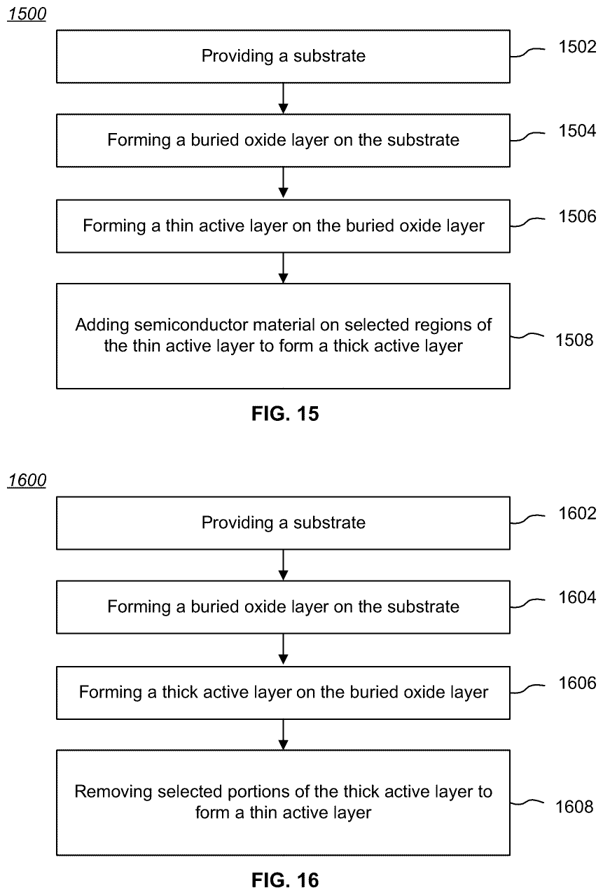

Another aspect of the invention includes methods for fabricating a substructure of a silicon-on insulator integrated circuit having dual-thickness active areas. For example, FIG. 15 is a process flow chart 1500 showing a first method for fabricating a substructure of an SOI IC having dual-thickness active areas. The method includes: providing a substrate (Block 1502); forming a buried oxide layer on the substrate (Block 1504); forming a thin active layer on the buried oxide layer (Block 1506); and adding semiconductor material on selected regions of the thin active layer to form a thick active layer (Block 1508).

As another example, FIG. 16 is a process flow chart 1600 showing a second method for fabricating a substructure of an SOI IC having dual-thickness active areas. The method includes: providing a substrate (Block 1602); forming a buried oxide layer on the substrate (Block 1604); forming a thick active layer on the buried oxide layer (Block 1606); and removing selected portions of the thick active layer to form a thin active layer (Block 1608).

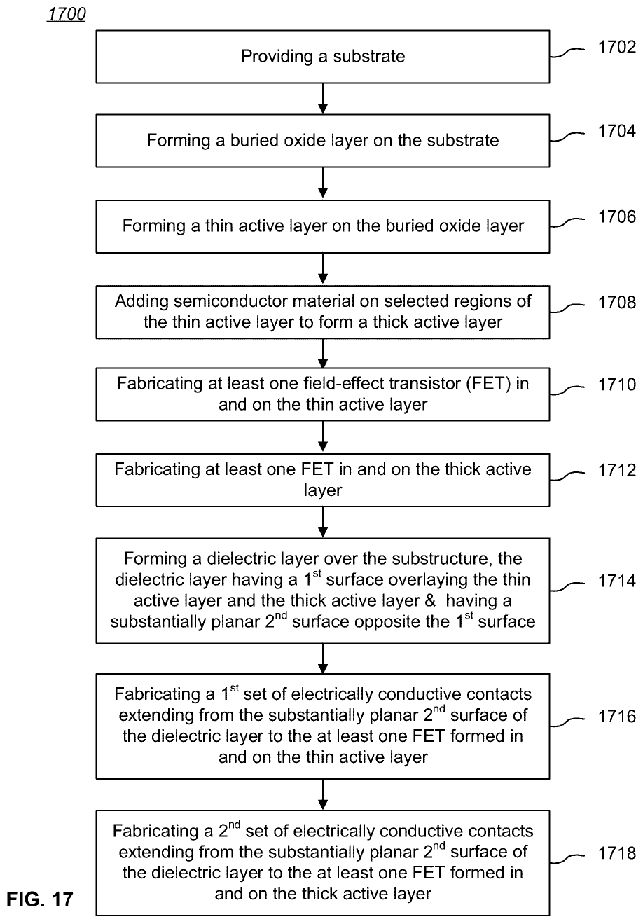

Another aspect of the invention includes methods for fabricating FET regions and device contacts in an SOI IC that has dual-thickness active areas. As one example, FIG. 17 is a process flow chart 1700 showing a first method for fabricating a substructure of an SOI IC having dual-thickness active areas. The method includes: providing a substrate (Block 1702); forming a buried oxide layer on the substrate (Block 1704); forming a thin active layer on the buried oxide layer (Block 1706); adding semiconductor material on selected regions of the thin active layer to form a thick active layer (Block 1708); fabricating at least one field-effect transistor (FET) in and on the thin active layer (Block 1710); fabricating at least one FET in and on the thick active layer (Block 1712); forming a dielectric layer over the substructure, the dielectric layer having a first surface overlaying the thin active layer and the thick active layer and having a substantially planar second surface opposite the first surface (Block 1714); fabricating a first set of electrically conductive contacts extending from the substantially planar second surface of the dielectric layer to the at least one FET formed in and on the thin active layer (Block 1716); and fabricating a second set of electrically conductive contacts extending from the substantially planar second surface of the dielectric layer to the at least one FET formed in and on the thick active layer (Block 1718).

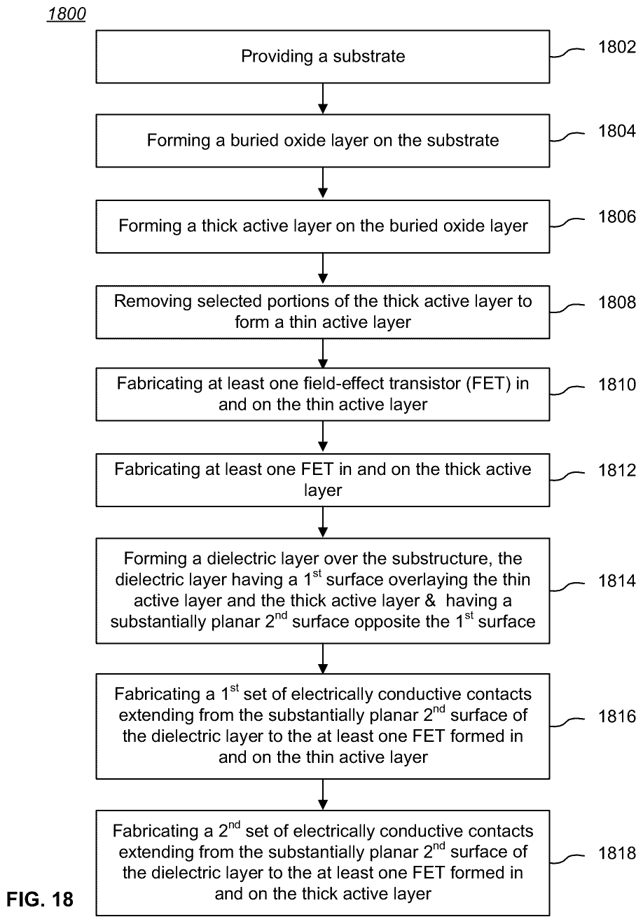

As another example, FIG. 18 is a process flow chart 1800 showing a second method for fabricating a substructure of an SOI IC having dual-thickness active areas. The method includes: providing a substrate (Block 1802); forming a buried oxide layer on the substrate (Block 1804); forming a thick active layer on the buried oxide layer (Block 1806); removing selected portions of the thick active layer to form a thin active layer (Block 1808); fabricating at least one field-effect transistor (FET) in and on the thin active layer (Block 1810); fabricating at least one FET in and on the thick active layer (Block 1812); forming a dielectric layer over the substructure, the dielectric layer having a first surface overlaying the thin active layer and the thick active layer and having a substantially planar second surface opposite the first surface (Block 1814); fabricating a first set of electrically conductive contacts extending from the substantially planar second surface of the dielectric layer to the at least one FET formed in and on the thin active layer (Block 1816); and fabricating a second set of electrically conductive contacts extending from the substantially planar second surface of the dielectric layer to the at least one FET formed in and on the thick active layer (Block 1818).

Additional aspects of the above methods may include one or more of the following: wherein the thin active layer has a thickness at or below about 550 Å; wherein the thick active layer has a thickness at or above about 1000 Å; wherein the thick active layer is formed by epitaxial growth of one or more semiconductor materials on selected regions of the thin active layer; wherein the thin active layer underlying the thick active layer is doped to lower a resistance of the thick active layer; further including forming a heat dissipation layer between the buried oxide layer and the thin and thick active layers; further including forming a silicon carbide layer between the buried oxide layer and the thin and thick active layers; wherein the substrate is one of P-type silicon, intrinsic silicon, high-resistivity silicon, porous silicon, or sapphire; wherein at least one FET fabricated in and on the thin active layer is separated from at least on FET fabricated in and on the thick active layer by a shallow-trench isolation structure; wherein at least one FET fabricated in and on the thin active layer and at least on FET fabricated in and on the thick active layer share a drain/source region; wherein at least one FET fabricated in and on the thick active layer includes a sidewall region configured to be in electrical contact with a corresponding electrically conductive contact within the second set of electrically conductive contacts; wherein the sidewall region is stepped; further including fabricating a substrate contact extending from the substantially planar second surface of the dielectric layer to at least the BOX layer; and/or wherein the substrate contact includes an outer shell of a conductive barrier material and a core of low-resistivity conductive material.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, BCD including LDMOS, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. An integrated circuit substructure having dual-thickness active areas, including:
(a) a substrate including a thin active layer and a thick active layer adjacent to the thin active layer;
(b) at least one field-effect transistor (FET) formed in and on the thin active layer;
(c) at least one FET formed in and on the thick active layer;
(d) a dielectric layer having a first surface overlaying the thin active layer and the thick active layer and having a substantially planar second surface opposite the first surface;
(e) a first set of electrically conductive contacts extending from the substantially planar second surface of the dielectric layer to the at least one FET formed in and on the thin active layer; and
(f) a second set of electrically conductive contacts extending from the substantially planar second surface of the dielectric layer to the at least one FET formed in and on the thick active layer.

2. The substructure of claim 1, wherein at least one FET formed in and on the thin active layer is separated from at least on FET formed in and on the thick active layer by a shallow-trench isolation structure.

3. The substructure of claim 1, wherein at least one FET formed in and on the thin active layer and at least on FET formed in and on the thick active layer share a drain/source region.

4. The substructure of claim 1, wherein at least one FET formed in and on the thick active layer includes a sidewall region configured to be in electrical contact with a corresponding electrically conductive contact within the second set of electrically conductive contacts.

5. The substructure of claim 4, wherein the sidewall region is stepped.

6. The substructure of claim 1, further including a substrate contact extending from the substantially planar second surface of the dielectric layer to at least the BOX layer.

7. The substructure of claim 6, wherein the substrate contact includes an outer shell of a conductive barrier material and a core of low-resistivity conductive material.

8. A substructure of a silicon-on insulator integrated circuit having dual-thickness active areas, including:
(a) a substrate;
(b) a buried oxide layer formed on the substrate;
(c) a thin active layer formed on the buried oxide layer; and
(d) a thick active layer formed on the buried oxide layer adjacent to the thin active layer;
(e) at least one field-effect transistor (FET) formed in and on the thin active layer;
(f) at least one FET formed in and on the thick active layer;
(g) a dielectric layer having a first surface overlaying the thin active layer and the thick active layer and having a substantially planar second surface opposite the first surface;
(h) a first set of electrically conductive contacts extending from the substantially planar second surface of the dielectric layer to the at least one FET formed in and on the thin active layer; and
(i) a second set of electrically conductive contacts extending from the substantially planar second surface of the dielectric layer to the at least one FET formed in and on the thick active layer.

9. The substructure of claim 8, wherein the thin active layer has a thickness at or below about 550 Å.

10. The substructure of claim 8, wherein the thick active layer has a thickness at or above about 1000 Å.

11. The substructure of claim 8, wherein the thick active layer is formed by epitaxial growth of one or more semiconductor materials on a selected region of the thin active layer.

12. The substructure of claim 11, wherein the thin active layer underlying the thick active layer is doped to lower a resistance of the thick active layer.

13. The substructure of claim 8, wherein the thin active layer is formed by removal of material from a selected region of the thick active layer.

14. The substructure of claim 8, further including a heat dissipation layer formed between the buried oxide layer and the thin and thick active layers.

15. The substructure of claim 8, further including a silicon carbide layer formed between the buried oxide layer and the thin and thick active layers.

16. The substructure of claim 8, wherein the substrate is one of P-type silicon, intrinsic silicon, high-resistivity silicon, porous silicon, or sapphire.

17. The substructure of claim 8, wherein the at least one FET formed in and on the thin active layer includes:
(a) a semiconductor well formed within the thin active layer;
(b) a gate structure formed on the semiconductor well;
(c) a source region formed within the semiconductor well adjacent a first side of the gate structure; and
(d) a drain region formed within the semiconductor well adjacent a second side of the gate structure.

18. The substructure of claim 8, wherein the at least one FET formed in and on the thick active layer includes:
(a) a semiconductor well formed within the thick active layer;
(b) a gate structure formed on the semiconductor well;
(c) a source region formed within the semiconductor well adjacent a first side of the gate structure; and
(d) a drain region formed within the semiconductor well adjacent a second side of the gate structure.

19.-25. (canceled)

26. The substructure of claim 18, wherein the semiconductor well includes:
(a) a first layer of silicon;
(b) a second layer of a silicon germanium alloy; and
(c) a third layer of tensile-strained silicon.

27. The substructure of claim 26, wherein the first layer of silicon is doped to have a lower resistance R_{B}.

28.-46. (canceled)
